(19) United States
(12) Patent Application Publication
(10) Pub. No.: US 2022/0222775 A1
(43) Pub. Date: Jul. 14, 2022

(54) SAMPLE OBSERVATION APPARATUS

(71) Applicant: Hitachi High-Tech Corporation, Minato-ku, Tokyo (JP)

(72) Inventors: Kazuo Ootsuga, Tokyo (JP); Terutaka Nanri, Tokyo (JP); Ryo Komatsuzaki, Tokyo (JP); Hiroyuki Chiba, Tokyo (JP)

(21) Appl. No.: 17/631,538

(22) PCT Filed: Sep. 24, 2019
(86) PCT No.: PCT/JP2019/037191

§ 371 Date: Jan. 31, 2022

(51) Int. Cl. G06T 3/40; G06T 7/00

(52) U.S. Cl. CPC G06T 3/4046; G06T 7/0002; G06T 2207/20084; G06T 2207/20081; G06T 2207/10056

(57) ABSTRACT

Provided is a sample observation apparatus including: a microscope that irradiates a sample with a probe, detects a signal from the sample, and outputs a detection signal; and a system that generates an image based on the detection signal received from the microscope. The system receives designation executed by a user for one or more trained models in a model database storing data of a plurality of trained models for estimating a high-quality image based on a low-quality image. The system generates and displays a current low-quality observation image based on the detection signal, and estimates and displays a high-quality image based on the current low-quality observation image according to each of the one or more trained models.

### TECHNICAL FIELD

The present invention relates to a sample observation apparatus.

### BACKGROUND ART

As a background art of the present disclosure, there is, for example, PTL 1. PTL 1 discloses, for example, “a sample observation apparatus including: a charged particle microscope that irradiates and scans a sample placed on a movable table with a charged particle beam to image the sample; an image storage unit that stores a low-quality image with poor image quality and a high-quality image with good image quality of the same portion of the sample acquired by changing observation conditions for imaging the sample with the charged particle microscope; a calculation unit that obtains an estimation processing parameter for estimating a high-quality image from the low-quality image using the low-quality image and the high-quality image stored in the image storage unit; a high-quality image estimation unit that estimates a high-quality image of a desired region by processing the low-quality image of a desired portion of the sample obtained by imaging the desired portion of the sample with the charged particle microscope using the estimation processing parameter obtained by the calculation unit; and an output unit that outputs the estimated high-quality image estimated by the high-quality image estimation unit” (Abstract).

### CITATION LIST

### Patent Literature

PTL 1: JP-A-2018-137275

### SUMMARY OF INVENTION

### Technical Problem

As described above, a learning method has been proposed in which a correspondence relationship between a low-quality image and a high-quality image is learned in advance, and the high-quality image is estimated based on the input low-quality image. By using learning type high-quality image estimation processing, it is possible to output a high-quality image even under an observation condition having high throughput.

In the learning type high-quality image estimation method as described above, it is important for high throughput observation to reduce time required for the user to acquire an appropriate model for estimating the high-quality image from the low-quality image.

### Solution to Problem

A sample observation apparatus according to one aspect of the invention includes: a microscope that irradiates a sample with a probe, detects a signal from the sample, and outputs a detection signal; and a system that generates an image based on the detection signal received from the microscope. The system receives designation executed by a user for one or more trained models in a model database storing data of a plurality of trained models for estimating a high-quality image based on a low-quality image, generates and displays a current low-quality observation image based on the detection signal, and estimates and displays a high-quality image based on the current low-quality observation image according to each of the one or more trained models.

### Advantageous Effect

According to a typical example of the invention, it is possible to shorten time required for the user to acquire an appropriate model for estimating a high-quality image based on a low-quality image.

Problems to be solved, configurations, and effects other than those described above will be apparent based on the description of the following embodiments.

### BRIEF DESCRIPTION OF DRAWINGS

FIG. 1 shows a configuration example of a sample observation apparatus including a scanning electron microscope.

FIG. 2 shows a configuration example of a control device, a storage device, and an arithmetic device of a control system.

FIG. 3 shows a flowchart of an example of a sample observation method.

FIG. 4 is a flowchart showing details of a saved image acquisition step.

FIG. 5 shows a training image data automatic acquisition setting screen.

FIG. 6 shows a screen that receives designation of a training time executed by a user.

FIG. 7 is a flowchart showing details of a high quality image estimation processing application step.

FIG. 8A shows a change in a display content of an estimation model selection screen.

FIG. 8B shows a change in a display content of the estimation model selection screen.

FIG. 8C shows a change in a display content of the estimation model selection screen.

FIG. 9 shows another example of a method for displaying a high quality image on the estimation model selection screen.

FIG. 10 shows a flowchart of another example of the sample observation method.

### DESCRIPTION OF EMBODIMENTS

Hereinafter, an embodiment will be described with reference to the accompanying drawings. The embodiment is merely an example for implementing the invention, and does not limit the technical scope of the invention. In the drawings showing the embodiment, elements having the same or similar configurations are denoted by the same reference numerals, and a repeated description thereof will be omitted.

An example of the sample observation apparatus disclosed below estimates a high-quality image based on a low-quality image, and displays the estimated high-quality image. The sample observation apparatus receives designation of one or more trained learning models (also simply referred to as models) executed by the user, and estimates a high-quality image based on the low-quality image according to the one or more designated trained models. Accordingly, it is possible to efficiently prepare an appropriate model for estimating the high-quality image based on the low-quality image.

Hereinafter, a sample observation apparatus according to an embodiment will be described. In an example of a sample observation apparatus described below, a scanning electron microscope (SEM) is used to image a sample. The scanning electron microscope is an example of a charged particle microscope. As the sample observation apparatus, another type of microscope that captures an image of the sample, for example, a microscope using ions or electromagnetic waves as a probe, a transmission electron microscope, or the like can be used. An image quality may change depending on an intensity of the probe and irradiation time.

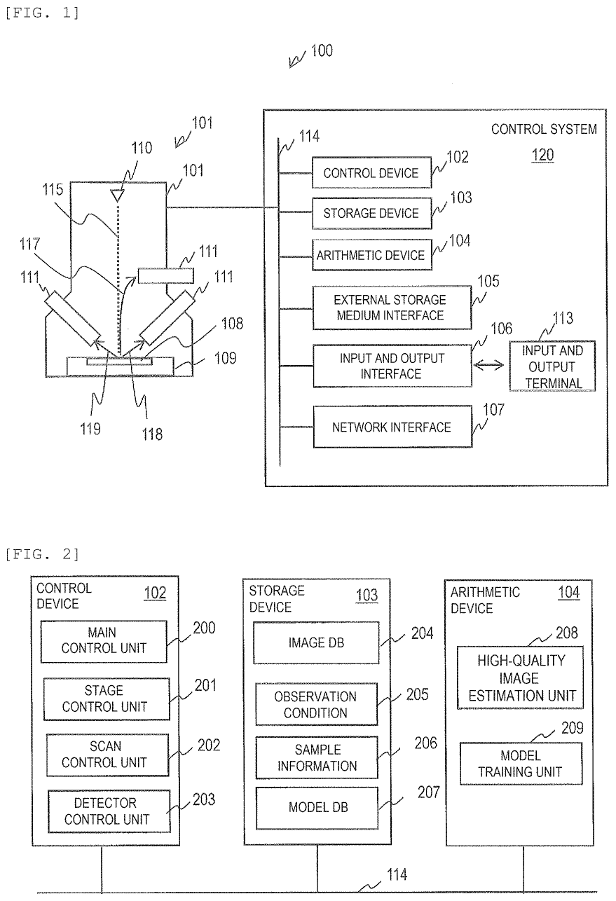

FIG. 1 shows a configuration example of a sample observation apparatus including an SEM according to the present embodiment. The sample observation apparatus 100 includes an SEM 101 that captures an image of a sample, and a control system 120. The control system 120 includes a control device 102 that controls components of the SEM 101 that captures an image of a sample, a storage device 103 that stores information, an arithmetic device 104 that executes a predetermined arithmetic operation, and an external storage medium interface 105 that communicates with an external storage medium.

The control system 120 further includes an input and output interface 106 that communicates information with an input and output terminal 113 used by a user (operator), and a network interface 107 that allows connection with an external network. Components of the control system 120 can communicate with one another via a network 114. The input and output terminal 113 includes input devices such as a keyboard and a mouse, and output devices such as a display device and a printer.

The SEM 101 includes a stage 109 on which a sample 108 is placed, an electron source 110 that generates primary electrons (probes) with which the sample 108 is irradiated, and a plurality of detectors 111 that detect signals from the sample 108.

The stage 109 carries the sample 108 to be observed and moves in an X-Y plane or in an X-Y-Z space. The electron source 110 generates a primary electron beam 115 with which the sample 108 is irradiated. The plurality of detectors 111 detect, for example, secondary electrons 117, reflected electrons 118, and X-rays 119 that are generated from the sample 108 irradiated with the primary electron beam 115. The SEM 101 further includes an electron lens (not shown) that converges the primary electron beam 115 on the sample 108, and a deflector (not shown) that allows the sample 108 to be scanned with the primary electron beam 115.

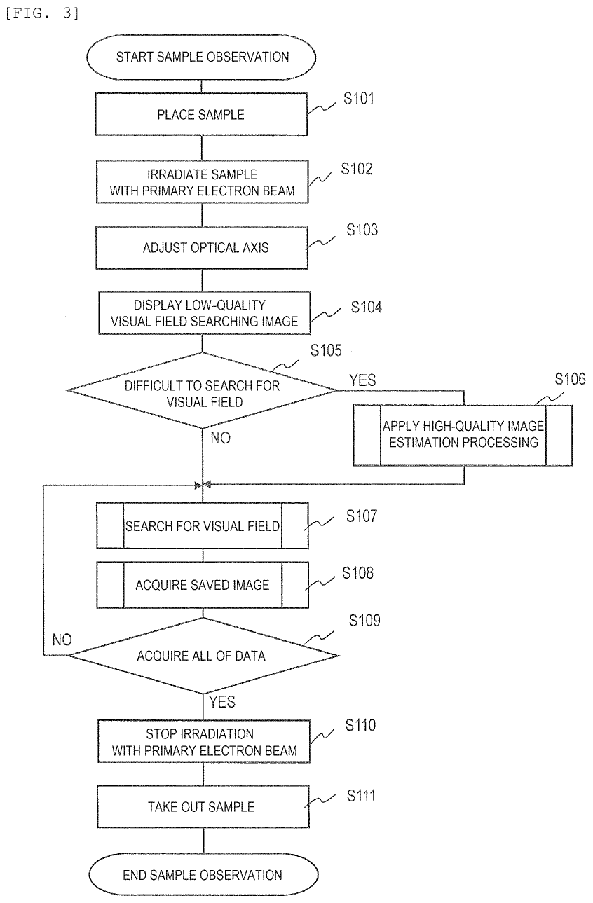

FIG. 2 shows a configuration example of the control device 102, the storage device 103, and the arithmetic device 104 of the control system 120. The control device 102 includes a main control unit 200, a stage control unit 201, a scan control unit 202, and a detector control unit 203. The control device 102 includes, for example, a processor and a memory that stores a program executed by the processor and data used by the program. For example, the main control unit 200 is a program module, and the stage control unit 201, the scan control unit 202, and the detector control unit 203 are electric circuits.

The stage control unit 201 controls the stage 109 to, for example, move and stop the stage 109 in the X-Y plane or in the X-Y-Z space. By moving the stage 109, a visual field of an observation image can be moved. The scan control unit 202 controls scanning of the sample 108 with the primary electron beam 115. Specifically, the scan control unit 202 controls a deflector (not shown) to control a scan region of the primary electron beam 115 on the sample 108 so as to obtain an image of a target visual field and a target imaging magnification. Further, the scan control unit 202 controls a scan speed of the primary electron beam 115 in the scan region.

The detector control unit 203 acquires a detection signal from the selected detector 111 in synchronization with scanning with the primary electron beam 115 driven by a deflector (not shown). The detector control unit 203 generates observation image data according to the detection signal from the detector 111, and transmits the observation image data to the input and output terminal 113. The input and output terminal 113 displays an observation image based on the received observation image data. The detector control unit 203 automatically adjusts parameters such as a gain and an offset of the detector 111 according to a user instruction from the input and output terminal 113 or according to a detection signal. By adjusting the parameters of the detector 111, a contrast and brightness of the image are adjusted. The contrast and brightness of the image can also be adjusted in the control device 102.

The storage device 103 may include, for example, one or more nonvolatile storage devices and/or one or more volatile storage devices. Each of the nonvolatile storage device and the volatile storage device includes a non-transitory storage medium that stores information (data).

In the configuration example shown in FIG. 2, the storage device 103 stores an image database (DB) 204, observation conditions 205, sample information 206, and a model database 207. The observation condition 205 indicates an apparatus condition of the current observation of the sample 108. The observation condition 205 includes, for example, an acceleration voltage of the primary electron beam 115 (probe), a probe current, a scan speed, a detector that detects a signal from the sample 108, a contrast, brightness, an imaging magnification, stage coordinates, and the like.

The observation condition 205 indicates an observation condition for each of different imaging modes of a sample image. As will be described later, the imaging mode includes an optical axis adjustment mode for generating a scanned image for optical axis adjustment, a visual field search mode for generating a scanned image for searching of a visual field, and a checking mode for checking a scanned image (to be stored) for observation purpose.

The sample information 206 includes information of the current sample 108, for example, information such as an identifier, a model number, and a category of the sample. Samples having a common model number are prepared based on the same design. The category of the sample includes, for example, a biological sample, a metal sample, a semiconductor sample, and the like.

The image database (DB) 204 stores a plurality of images and accompanying information thereof. The accompanying information of the images includes information on the sample to be observed and an apparatus condition (observation condition) in imaging of the image. The information on the sample includes, for example, information such as the identifier of the sample, the model number of the sample, and the category of the sample. The accompanying information of a pair of an input image (low quality image) and a teacher image (high quality image) used for model training associates images constituting the pair with each other.

The model database 207 stores configuration data of each of a plurality of trained models and accompanying information of the models. The configuration data of one model includes a learning parameter set updated by training. As the model, for example, a convolutional neural network (CNN) can be used. A type of the model is not particularly limited, and a model (machine learning algorithm) of a type different from that of a neural network can also be used.

In the example described below, configurations other than the learning parameter sets of all models are common, and the learning parameter sets may be different for each model. In another example, the model database 207 may store models having different components other than the learning parameter sets. For example, the model database 207 may store neural networks having different hyperparameters or models having different algorithms.

The model stored in the model database 207 is trained so as to relatively estimate the high-quality image based on the low-quality image. A low quality and a high quality indicate relative qualities between two images. The input image in the training data is a low-quality image of an observation target captured by the SEM 101, and the teacher image is a high-quality image of the same observation target captured by the SEM 101. The training data is stored in the image database 204 as described above.

The low-quality image includes an image of a low signal to noise ratio (SNR), and includes, for example, an image generated with a small amount of signal from the sample, an image blurred due to out-of-focus, and the like. The high quality image corresponding to the low SNR image is an image having a higher SNR than the low SNR image. In the example described below, an image pair includes a low-quality image captured in a high-speed scan and a high-quality image captured in a low-speed scan or a high-quality image obtained by frame integration in a high-speed scan is used for model training. The low-speed scan and the high-speed scan show a relative relationship of scan speeds.

Each model is trained by a plurality of pairs of the low-quality image and the high-quality image. In an example described below, values of some condition items related to the image quality of the low-quality images of the plurality of pairs are common. For example, the values of the acceleration voltage, the probe current, the scan speed, the type of the detector, the contrast, the brightness, and the like are common. An observation condition model is trained by, for example, low-quality images of different regions under the above-described common conditions of the same sample and high-quality images under the above-described common conditions corresponding to the low-quality images. The high-quality image may be captured under different conditions.

Training data of one model can include image data of different samples. For example, the training data can include one or a plurality of image pairs commonly used for a plurality of models, in addition to an image of one sample. A common image pair is an image of a sample of the same category as the above-described one sample, and for example, categories such as a biological sample, a metal sample, and a semiconductor sample are defined. Accordingly, versatility of the model can be improved. The training data may include low-quality images in which values of the condition items do not completely match but are similar to each other. For example, the training data may include a low-quality image in which a difference in the value of each item is within a predetermined threshold value.

The arithmetic device 104 includes a high-quality image estimation unit 208 and a model training unit 209. The arithmetic device 104 includes, for example, a processor and a memory that stores a program executed by the processor and data used by the program. The high-quality image estimation unit 208 and the model training unit 209 are program modules.

The high-quality image estimation unit 208 estimates a high-quality image based on the input low-quality image according to the model. The model training unit 209 updates learning parameters of the model using the training data. Specifically, the model training unit 209 inputs the low-quality image of the training data to the high-quality image estimation unit 208 that operates according to the selected model, and acquires the estimated high-quality image.

The model training unit 209 calculates an error between the high-quality image which is the teacher image in the training data and the estimated high-quality image, and updates the learning parameter by back propagation so as to reduce the error. The model training unit 209 repeats updating of the learning parameter for each of the plurality of image pairs included in the training data. Training of a machine learning model is a widely known technique, and a detailed description thereof will be omitted.

As described above, in one example, the control device 102 and the arithmetic device 104 can include a processor and a memory. The processor executes various types of processing according to programs stored in the memory. The processor operates according to the programs, so that various function units are implemented. The processor can include a single processing unit or a plurality of processing units, and can include a single or a plurality of arithmetic units, or a plurality of processing cores.

The program executed by the processor and the data used for the program are stored in, for example, the storage device 103 and loaded into the control device 102 and the arithmetic device 104. For example, the data of the model executed by the arithmetic device 104 is loaded from the model database 207 into the memory of the arithmetic device 104. At least a part of the functions of the control device 102 and the arithmetic device 104 may be implemented by a logic circuit different from the processor, and the number of devices in which the functions of the control device 102 and the arithmetic device 104 are implemented is not limited.

An example of a sample observation method will be described with reference to the flowchart in FIG. 3. In the following description, an instruction of the user is given from the input and output terminal 113 via the input and output interface 106. First, the user places the sample 108 to be observed on the stage 109 (S101). When the user starts an operation via the input and output terminal 113, the main control unit 200 displays a microscope operation screen on the input and output terminal 113.

Next, according to a user instruction, the scan control unit 202 irradiates the sample 108 with the primary electron beam 115 (S102). The user adjusts an optical axis while checking the image of the sample 108 at the input and output terminal 113 (S103). According to an instruction from the user to start optical axis adjustment, the main control unit 200 displays an optical axis adjustment screen on the input and output terminal 113. The user can adjust the optical axis on the optical axis adjustment screen. The main control unit 200 controls an aligner (not shown) for adjusting an optical axis of the SEM 101 according to a user instruction.

The optical axis adjustment screen displays the sample image during the optical axis adjustment in real time. The user adjusts the optical axis to an optimum position while viewing the sample image. For example, the main control unit 200 performs wobbling in which the excitation current of an electron lens such as a condenser lens or an objective lens is periodically changed, and the user adjusts the optical axis such that the movement of the sample image is minimized while viewing the sample image.

In the optical axis adjustment, the main control unit 200 sets other components of the SEM 101 and the control device 102 according to the observation condition of the optical axis adjustment mode indicated by the observation condition 205. The detector control unit 203 processes the detection signal from the detector 111 indicated by the observation condition 205 to generate a sample image (scanned image) of the observation region for optical axis adjustment. The main control unit 200 displays the scanned image generated by the detector control unit 203 on the input and output terminal 113.

The scanned image for optical axis adjustment is generated at a high scan speed and is displayed at a high frame rate (high image update speed). The scan control unit 202 moves the primary electron beam 115 on the sample 108 at a scan speed in the optical axis adjustment mode. The scan speed for the optical axis adjustment is higher than the scan speed for generating the sample image to be stored. The generation of one image is completed in, for example, several tens of milliseconds, and the user can check the sample image in real time.

After the completion of the optical axis adjustment, the main control unit 200 displays a visual field searching screen including a low-quality sample image (low-quality visual field searching image) on the input and output terminal 113 according to an instruction to start searching for a visual field from the user (S104). A visual field search is an action of searching for a target observation visual field while performing focus adjustment and astigmatism adjustment in parallel. The visual field searching screen displays the sample image during visual field searching in real time. In the visual field searching, the main control unit 200 receives a movement of the visual field and a change of the imaging magnification from the user.

In the visual field searching, the main control unit 200 sets other components of the SEM 101 and the control device 102 according to the observation condition of the visual field search mode indicated by the observation condition 205. The detector control unit 203 processes the detection signal from the detector 111 indicated by the observation condition 205 to generate a sample image (scanned image) of the observation region for visual field searching. The main control unit 200 displays the scanned image generated by the detector control unit 203 on the input and output terminal 113.

The scanned image for visual field searching is generated at a high scan speed and is displayed at a high frame rate (high image update speed). The scan control unit 202 moves the primary electron beam 115 on the sample 108 at a scan speed in the visual field search mode. The scan speed for the visual field searching is higher than the scan speed for generating the sample image to be stored. The generation of one image is completed in, for example, several tens of milliseconds, and the user can check the sample image in real time.

Since the scanned image for visual field searching is generated at a high scan speed, the scanned image is a low-quality image, and the SNR thereof is lower than the SNR of the sample image in which the observation target region is stored. When the user determines that it is difficult to appropriately search for a visual field based on a low-quality image for visual field searching (S105: YES), the user instructs the control device 102 from the input and output terminal 113 to apply the high-quality image estimation processing to the image for visual field searching.

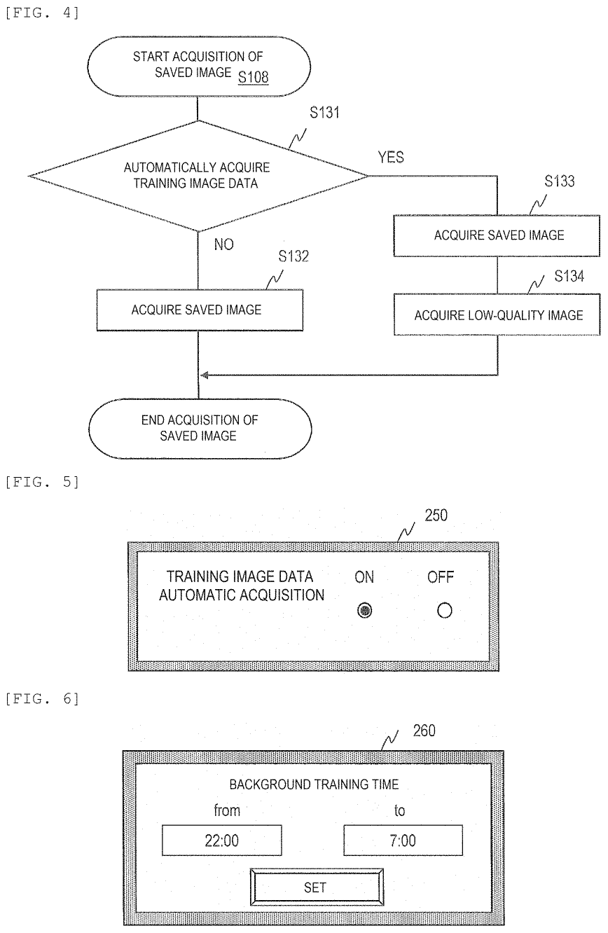

The main control unit 200 executes application of high-quality image estimation processing in response to an instruction from the user (S106). The application of the high-quality image estimation processing will be described later in detail with reference to FIG. 4. When the high-quality image estimation processing is applied, the high-quality image estimation unit 208 of the arithmetic device 104 estimates (generates) a high-quality image based on the low-quality scanned image generated by the detector control unit 203 according to the designated high-quality image estimation model. The main control unit 200 displays the high-quality image generated by the high-quality image estimation unit 208 on the visual field searching screen. The generation of the high-quality image is completed in, for example, several tens of milliseconds, and the user can check the high-quality sample image in real time.

When the user determines that the appropriate visual field searching is possible based on the low-quality image for visual field searching (S105: NO), the main control unit 200 continues displaying the low-quality scanned image generated by the detector control unit 203 on the visual field searching screen.

The user executes visual field searching on the visual field searching screen (S107). In the input and output terminal 113, the user moves the visual field while referring to the sample image (low-quality scanned image or high-quality estimated image) for visual field searching, and changes the imaging magnification as necessary to search for the target observation visual field. The stage control unit 201 moves the visual field by moving the stage 109 in response to a user instruction to move a large visual field. The scan control unit 202 changes the scan region corresponding to the visual field in response to the user instruction to move a small visual field and change the imaging magnification.

When a target observation visual field is found, the user performs final focus adjustment and astigmatism adjustment as necessary, and then instructs the input and output terminal 113 to acquire a saved image of the target observation visual field. The main control unit 200 generates a saved image in response to a user instruction, and stores the saved image in the image database 204 of the storage device 103 (S108).

FIG. 4 is a flowchart showing the details of the saved image acquisition step 3108. The main control unit 200 determines whether automatic acquisition of training image data is designated (S131). FIG. 5 shows a training image data automatic acquisition setting screen 250. The user previously sets whether training image data is automatically acquired in the input and output terminal 131. The user sets ON or OFF of automatic acquisition of training image data on the training image data automatic acquisition setting screen 250. The main control unit 200 holds information of the setting designated on the training image data automatic acquisition setting screen 250.

When automatic acquisition of training image data is not designated (S131: NO), the main control unit 200 acquires a saved image (S132). Specifically, the main control unit 200 sets other components of the SEM 101 and the control device 102 according to the observation condition of the checking mode indicated by the observation condition 205. The observation condition of the checking mode is, for example, the same as the visual field search mode and/or the optical axis adjustment mode in elements other than a scan condition (scan region and scan speed).

The scanned image for saving is generated at a low scanning speed. The scan control unit 202 moves the primary electron beam 115 on the sample 108 at a scan speed in the checking mode. The scan speed for generating a saved image (target image) is lower than the scan speed for generating a sample image for optical axis adjustment and visual field searching. The generation of one image is completed in, for example, several tens of seconds.

The detector control unit 203 processes the detection signal from the detector 111 indicated by the observation condition 205 to generate a sample image (scanned image) in a designated visual field. The main control unit 200 displays the scanned image generated by the detector control unit 203 on the input and output terminal 113 to allow the user to check the scanned image. The main control unit 200 stores the acquired scanned image in the image database 204 of the storage device 103 in response to an instruction from the user. The main control unit 200 stores the accompanying information including the information on the sample and the observation condition in the image database 204 in association with the image.

When automatic acquisition of training image data is designated (S131: YES), the main control unit 200 acquires one or a plurality of low-quality images after acquisition (S133) of the saved image (S134). The main control unit 200 may acquire one or a plurality of low-quality images before and/or after acquisition of the saved image.

The main control unit 200 generates one or a plurality of low-quality images, and stores the low-quality images in the image database 204 in association with the saved images together with the accompanying information including the observation conditions. Specifically, the main control unit 200 generates a scanned image at a higher scan speed in the same visual field (scan region) as the saved image. The observation condition of the low-quality image is, for example, the same as the observation condition in the visual field search mode or the optical axis adjustment mode. When a plurality of low-quality images are acquired, the low-quality images may include low-quality images whose observation conditions are the same as those in the visual field search mode or the optical axis adjustment mode. As will be described later, a pair of a low-quality image and a high-quality image is used for training of a present or new estimation model (machine learning model).

In one example, training of the estimation model is executed outside observation time of the user (background training). Accordingly, it is possible to prevent the training of the estimation model from hindering the observation of the sample executed by the user. For example, the main control unit 200 does not train the estimation model while the user logs in a system for observation.

In another example, the main control unit 200 receives designation of the training time executed by the user in order to specify the observation time of the user. FIG. 6 shows a screen 260 that receives designation of the training time executed by the user. The user inputs a start time and an end time of the background training, and checks the start time and the end time by clicking a setting button.

Returning to FIG. 3, when the user desires to acquire a saved image of another observation target region (S109: NO), the user returns to step S107 and starts a visual field searching. When all observation images desired by the user are acquired and stored in the image database 204 together with the accompanying information of the observation images (S109: YES), the user executes an instruction to stop the irradiation with the primary electron beam 115 via the input and output terminal 113, and the main control unit 200 stops the irradiation with the primary electron beam 115 in response to the instruction (S110). Finally, the user takes out the sample 108 from the SEM 101 (S111).

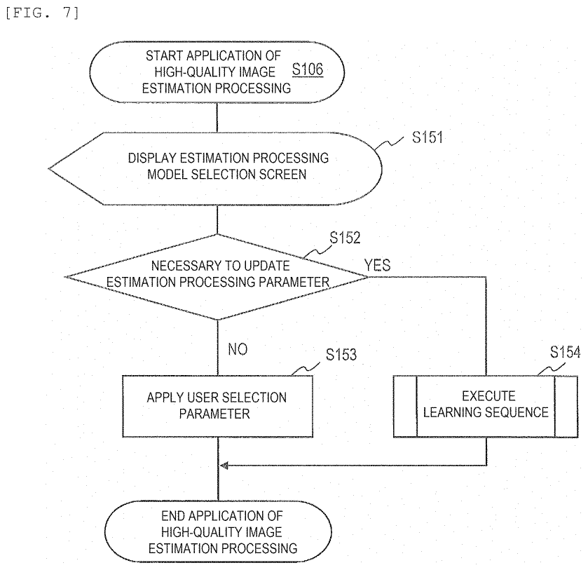

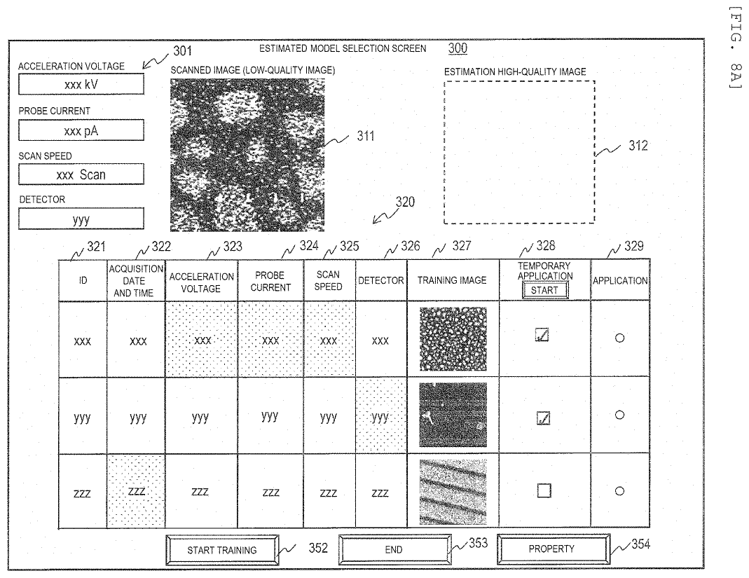

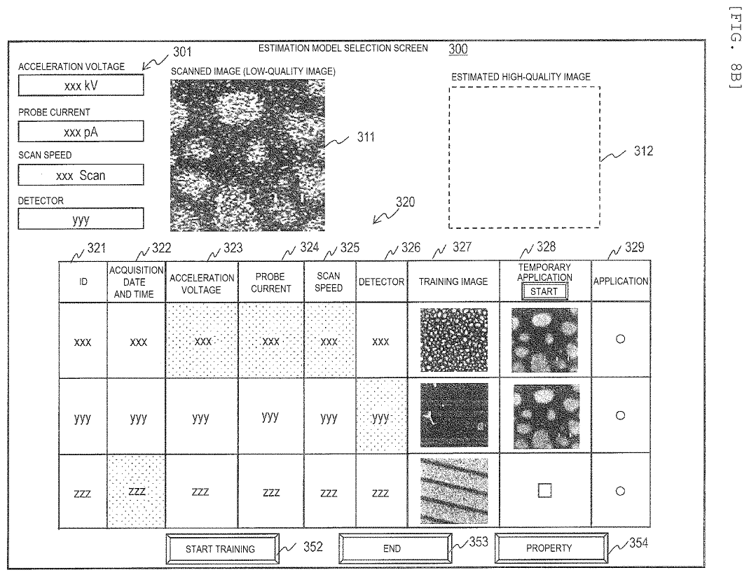

The high-quality image estimation processing application step S106 will be described in detail with reference to the flowchart in FIG. 7. As described above, when the user determines that it is difficult to search for a visual field based on the low-quality scanned image, the main control unit 200 starts the present step S106 in response to an instruction from the user.

First, the main control unit 200 displays an estimation model selection screen on the input and output terminal 113 (S151). The estimation model selection screen allows the user to designate a model (parameter set) for estimating a high-quality image based on a low-quality scanned image in visual field searching.

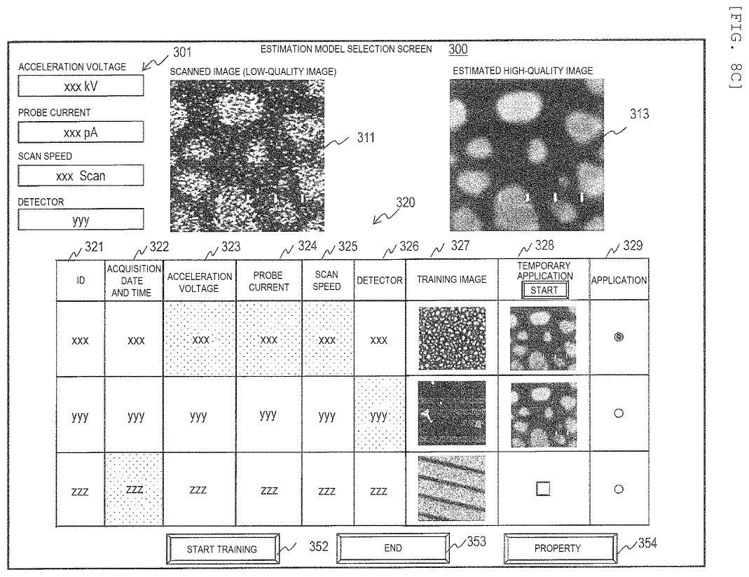

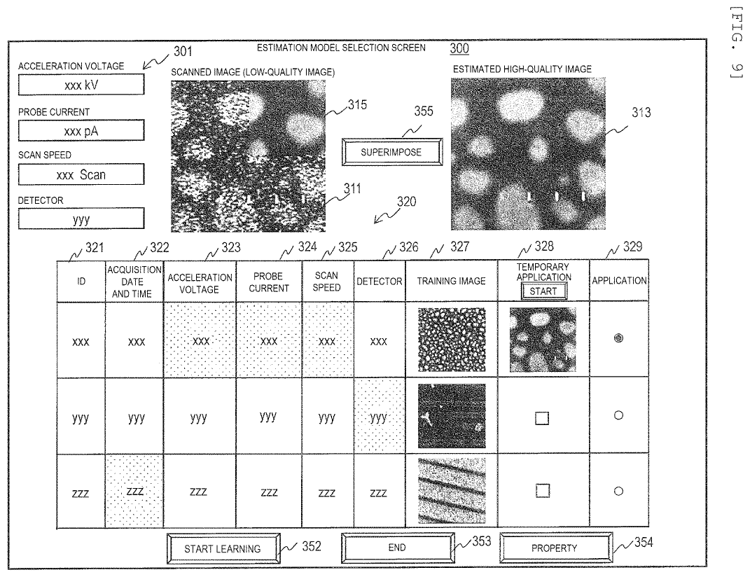

FIGS. 8A, 8B and 8C show a change in a display content of the estimation model selection screen 300. The display content of the estimation model selection screen 300 changes from an image in FIG. 8A to an image in FIG. 8B and further changes from the image in FIG. 8B to an image in FIG. 8C in response to the user instruction.

As shown in FIG. 8A, the estimation model selection screen 300 displays a current scanned image (low-quality image) 311 and an observation condition 301 of a current scanned image 311. In the present example, the observation condition 301 indicates the acceleration voltage of the probe, the probe current, the scan speed, and a detector being used. The estimation model selection screen 300 includes a region 312 in which a high-quality image generated based on the current scanned image 311 according to the designated model is displayed.

The estimation model selection screen 300 further displays a candidate model table 320 indicating information on one or more candidate models selected from the model database 207. The candidate model table 320 includes an ID field 321, an acquisition date and time field 322, an acceleration voltage field 323, a probe current field 324, a scan speed field 325, a detector field 326, a training image field 327, a temporary application field 328, and an application field 329.

The ID field 321 indicates the ID of a candidate model. The acquisition date and time field 322 indicates a creation date and time of the candidate model. The acceleration voltage field 323, the probe current field 324, the scan speed field 325, and the detector field 326 indicate observation conditions of an input image (low-quality image) in training image data of the candidate model. The training image field 327 indicates an input image (low-quality image) or a teacher image (high-quality image) in the training data of the candidate model.

The temporary application field 328 includes a button for selecting a candidate model to be temporarily applied, and further displays a high-quality image estimated according to the selected candidate model. The application field 329 includes a button for selecting a candidate model to be finally applied. The high-quality image estimated according to the candidate model selected in the application field 329 is displayed in the region 312.

The estimation model selection screen 300 displays a training start button 352, an end button 353, and a property button 354. The training start button 352 is a button for instructing acquisition of new training image data of the current sample 108 and generation of a new model according to the new training data. The end button 353 is a button for ending a selection of the estimation model and checking the estimation model to be applied. The property button 354 is a button for selecting an observation condition or a sample category that is not displayed and adding the selected observation condition or the sample category to a display image.

The main control unit 200 selects a candidate model from the model database 207 based on a sample to be observed and/or the observation condition. In the example described below, the main control unit 200 refers to the sample to be observed and the observation condition. The main control unit 200 selects a model of the sample and the observation condition similar to the current sample 108 and the observation condition as the candidate model. Accordingly, it is possible to select a model capable of more appropriately estimating a high-quality image.

For example, the main control unit 200 defines a vector representing the value of each item of the category of the sample and the observation condition, and determines a similarity degree based on the distance between the vectors. In another example, the main control unit 200 selects, as the candidate model, a model having a high similarity degree to the current sample 108 and the observation condition among models having the same or similar sample categories. The similarity degree is determined according to, for example, the number of items whose values match or approximate to each other in the observation condition. A range of approximation of the value of the similar category and an item of each category is defined in advance.

In the example shown in FIG. 8A, the observation conditions referred to for determining the similarity degree are the acquisition date and time, the acceleration voltage, the probe current, the scan speed, and the detector. A part of these observation conditions may be omitted, and other observation conditions such as a contrast and brightness may be added. The main control unit 200 may present a predetermined number of models from a model having the highest similarity degree to a current sample and the observation condition, or may present a model having a similarity degree greater than a predetermined value.

In the example shown in FIG. 8A, the candidate model table 320 highlights a cell of the item that matches or is closest to the current observation condition in a record of each candidate model. For example, in the observation condition of the candidate model of an ID “xxx”, the acceleration voltage, the probe current, and the scan speed match the current observation condition.

In the observation condition of the candidate model with an ID “yyy”, the detector matches the current observation condition. An acquisition date and time of an ID “zzz” is the latest (closest to the current date and time) in the candidate model, and a cell of the ID “zzz” is highlighted. According to such highlighting, the user can immediately specify a candidate model close to the current observation condition in an item of interest in the current observation condition. A manner of highlighting is any manner. The main control unit 200 may highlight a cell in a predetermined range from the value of each item of the current observation condition. The highlighting may be omitted.

When the user selects a check box of one or a plurality of candidate models in the temporary application field 328 and clicks a “start” button, the main control unit 200 displays the high-quality image estimated according to the corresponding candidate model in the cell of the selected check box in the temporary application field 328. In the example in FIG. BA, the candidate model of the ID “xxx” and the candidate model of the ID “yyy” are selected.

FIG. 8B shows a result of clicking the “start” button in the temporary application field 328 in FIG. 8A. The estimated high-quality images of the candidate model of the ID “xxx” and the candidate model of the ID “yyy” are displayed in the temporary application field 328. When the “start” button in the temporary application field 328 is clicked, the main control unit 200 acquires the parameter set of the selected candidate model from the model database 207. The main control unit 200 sequentially transmits the acquired parameter sets to the arithmetic device 104, and receives the estimated high-quality image. The main control unit 200 displays the high-quality image in the corresponding cell of the temporary application field 328.

After receiving the parameter set, the high-quality image estimation unit 208 of the arithmetic device 104 acquires the scanned image generated by the detector control unit 203, and generates a high-quality image based on the scanned image. The high-quality image estimation unit 208 repeats this processing for different parameter sets.

When the user selects any of the candidate models in the application field 329, the main control unit 200 displays the high-quality image according to the selected candidate model in the region 312. In the example in FIG. 8B, the candidate model of the ID “xxx” is selected.

FIG. 8C shows a result of selecting the candidate model of the ID “xxx” in the application field 329 in FIG. 8B. The high-quality image 313 estimated according to the candidate model of the ID “xxx” is displayed side by side with the current scanned image 311. When one candidate model is selected in the application field 329, the main control unit 200 acquires a parameter set of the candidate model from the model database 207. The main control unit 200 transmits the acquired parameter set to the arithmetic device 104.

After receiving the parameter set, the high-quality image estimation unit 208 of the arithmetic device 104 sequentially acquires the scanned image generated by the detector control unit 203, sequentially generates high-quality images based on the scanned images, and transmits the high-quality images to the control device 102. The main control unit 200 updates a display image of the region 312 according to the sequentially received high-quality images.

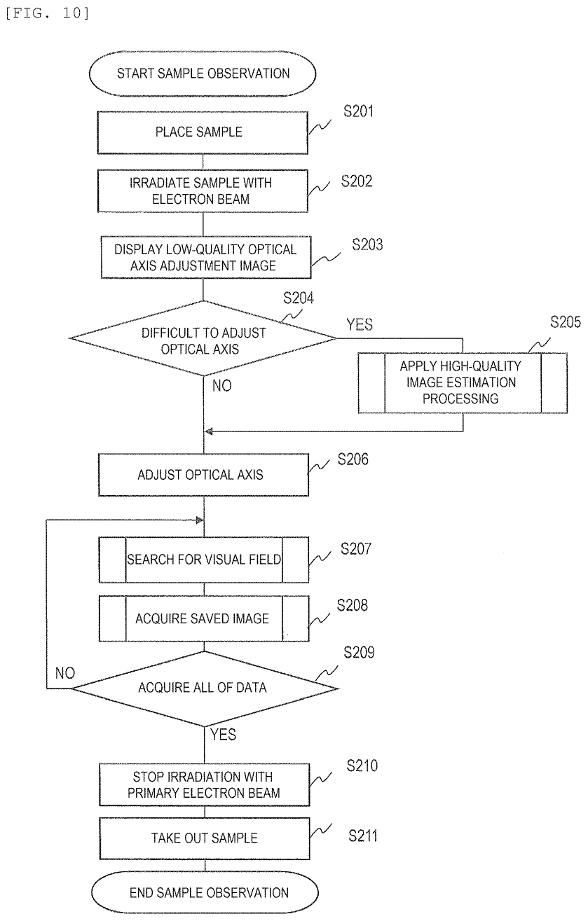

FIG. 9 shows an example of another display method of the high-quality image according to the estimation model selected in the application field 329. The estimation model selection screen 300 shown in FIG. 9 displays the high-quality image 315 of a partial region in the visual field in a manner of being superimposed on the low-quality scanned image 311. Accordingly, it is easier for the user to compare the low-quality image and the high-quality image. When the user clicks a “superimpose” button 355, the main control unit 200 extracts a predetermined region of the estimated high-quality image 313 and superimposes the predetermined region on a corresponding region of the low-quality scanned image 311. The “superimpose” button 355 may be omitted, and the high-quality image 315 may be always superimposed on the low-quality scanned image 311. The estimated high-quality image 313 may be omitted.

As described above, the high-quality image estimated according to one or more candidate models (parameter sets) stored in the model database 207 is displayed. Accordingly, the user can designate an appropriate high-quality image estimation model in a short time. By presenting the candidate model from the trained model, it is possible to reduce learning time of the machine learning model.

When the user determines that an appropriate high-quality image cannot be estimated according to any of the presented candidate models, the user clicks the training start button 352. In response to the click of the training start button 352, the main control unit 200 acquires training image data of the current sample 108, and generates an estimation model suitable for observation of the current sample 108 based on the training data.

The main control unit 200 acquires, in each of the different visual fields, a high-quality scanned image captured at a low scanning speed or obtained by frame integration at a high scanning speed and a low-quality scanned image at a high scanning speed. The main control unit 200 moves the visual field by the scan control unit 202 and the stage control unit 201, and controls the scan speed by the scan control unit 202. The detector control unit 203 generates a low-quality scanned image and a high-quality scanned image in each visual field. The low-quality scanned image and the high-quality scanned image are included in training data for generating a new estimation model.

The training data may include a plurality of representative image pairs of the same category as the current sample 108. The image pair includes a low-quality scanned image and a high-quality scanned image, and an observation condition of the image pair coincides with a current observation condition or is within a predetermined similarity range. Accordingly, versatility of the estimation model can be improved.

The main control unit 200 trains an estimation model having an initial parameter set or a trained parameter set based on the training data. In one example, the main control unit 200 receives selection executed by the user as to whether to use the initial parameter set or the trained parameter set. The main control unit 200 receives selection of the trained parameter set to be re-trained executed by the user. The trained parameter set is selected from, for example, candidate models. The main control unit 200 may select a candidate model (parameter set) having the highest similarity degree to the current sample and the observation condition as a model for re-training.

The main control unit 200 transmits a training request including a parameter set to be trained and training data to the arithmetic device 104. The model training unit 209 of the arithmetic device 104 updates the parameter set using the training data and generates a new estimation model. The model training unit 209 calculates an error between the high-quality scanned image which is the teacher image in the training data and the estimated high-quality image, and updates the parameter set by back propagation so as to reduce the error. The model training unit 209 repeats updating of the parameter set for each of the plurality of image pairs included in the training data.

When the training of the estimation model ends, the main control unit 200 acquires a new model (parameter set) from the model training unit 209, and displays the estimated high-quality image generated by the high-quality image estimation unit 208 using the parameter set in the region 312 or in the visual field searching screen. The main control unit 200 stores the new estimation model in the model database 207 together with the accompanying information, and further stores the training data in the image database 204 together with the accompanying information.

As described above, in a case in which an appropriate high-quality image cannot be estimated according to a present estimation model, a new estimation model trained according to the image of the current sample is generated, so that it is possible to more appropriately estimate a high-quality image based on the low-quality image of the current sample.

In the observation method described with reference to the flowchart shown in FIG. 3, a high-quality image is estimated based on a low-quality scanned image when necessary in the visual field searching after the optical axis adjustment. In another example, the control system 120 may estimate the high-quality image based on the low-quality scanned image in the optical axis adjustment. Accordingly, it is possible to more appropriately adjust the optical axis.

FIG. 10 is a flowchart of an observation method for estimating the high-quality image based on the low-quality scanned image in optical axis adjustment and visual field searching when necessary.

Steps S201 and S202 are similar as steps S101 and S102 in FIG. 3. In step S203, in response to the instruction from the user to start the optical axis adjustment, the main control unit 200 causes the input and output terminal 113 to display an optical axis adjustment screen including a low-quality sample image (optical axis adjustment image).

As described with reference to FIG. 3, an optical axis adjustment image is a low-quality scanned image. When the user determines that it is difficult to appropriately adjust the optical axis based on the low-quality image for optical axis adjustment (S204: YES), the user instructs the control device 102 via the input and output terminal 113 to apply the high-quality image estimation processing to the image for optical axis adjustment.

The main control unit 200 executes application of the high-quality image estimation processing in response to the instruction from the user (S205). The high-quality image estimation processing application S205 is substantially the same as the high-quality image estimation processing application S105 in FIG. 3. The displayed low-quality scanned image is an optical axis adjustment image. When the user determines that appropriate optical axis adjustment is possible based on the low-quality optical axis adjustment image (S204: NO), the high-quality image estimation processing application S205 is omitted.

When the high-quality image estimation processing application S205 is executed, a high-quality image is generated based on the low-quality scanned image and is displayed in the optical axis adjustment S206 and the visual field searching S207. Other points of the optical axis adjustment S206 are similar as those in the step S103 in FIG. 3. Steps S207 to S211 are similar as the steps S107 to S111 in FIG. 3.

The above example is applied to the visual field searching when high-quality image estimation is applied to the optical axis adjustment. In another example, in each of the optical axis adjustment and the visual field searching, the control system 120 may receive, from the user, a designation of whether the high-quality image estimation is applied. When the observation conditions of the scanned image for optical axis adjustment and the scanned image for visual field searching are different from each other, a user designation of the estimation model to be applied may be received in each of the observation conditions (for example, steps S205 and S106).

The invention is not limited to the above embodiments, and includes various modifications. For example, the embodiments described above are described in detail for easy understanding of the invention, and the invention is not necessarily limited to those including all the configurations described above. A part of the configuration according to one embodiment can be replaced with the configuration according to another embodiment, and the configuration according to one embodiment can be added to the configuration according to another embodiment. A part of the configuration according to the embodiment may be added, deleted, or replaced with another configuration.

Each of the configurations, functions, processing units, or the like described above may be partially or entirely implemented by hardware by being designed using an integrated circuit. The above configurations, functions, and the like may also be implemented by software by a processor interpreting and executing a program for implementing the functions. Information of programs, tables, files or the like for implementing the functions can be stored in a recording device such as a memory, a hard disk, and a solid state drive (SSD), or a recording medium such as an IC card and an SD card.

Control lines and information lines are those that are considered necessary for the description, and not all control lines and the information lines on the product are necessarily shown. In practice, it may be considered that almost all configurations are connected to one another.

1. A sample observation apparatus comprising:
a microscope that irradiates a sample with a probe, detects a-signal-secondary electrons from the sample, and outputs a detection signal; and
a system that generates an image based on the detection signal received from the microscope, wherein
the system
receives designation executed by a user for one or more trained models in a model database storing data of a plurality of trained models for estimating a high-quality image based on a low-quality image,
generates and displays a current low-quality observation image based on the detection signal, and
estimates and displays a high-quality image based on the current low-quality observation image according to each of the one or more trained models.

2. The sample observation apparatus according to claim 1, wherein
the system
selects one or more candidate models as candidates for designation executed by the user from the plurality of trained models based on a relationship between a current observation condition and each of observation conditions of the plurality of trained models,
displays information of the one or more candidate models, and
receives, in the one or more candidate models, the designation executed by the user for the one or more trained models.

3. The sample observation apparatus according to claim 2, wherein
the system displays observation conditions of the one or more candidate models.

4. The sample observation apparatus according to claim 3, wherein
the observation condition includes at least one of an acceleration voltage, a probe current, a scan speed, a detector, a contrast, and brightness.

5. The sample observation apparatus according to claim 3, wherein
in the observation conditions of the one or more candidate models, an item having a predetermined relationship with the current observation condition is highlighted.

6. The sample observation apparatus according to claim 1, wherein
the system displays a portion of the estimated high-quality image in a manner of being superimposed on a corresponding portion of the current low-quality image.

7. The sample observation apparatus according to claim 1, wherein
a first low-quality image having the same visual field as a first high-quality image is generated before or after generating the first high-quality image, and
a pair of the first high-quality image and the first low-quality image is included in training data of a new model.

8. The sample observation apparatus according to claim 7, wherein
the system performs training of the new model outside observation time of the sample.

9. The sample observation apparatus according to claim 1, wherein
the trained model is trained according to a plurality of training image pairs each including an input image and a teacher image,
the input image is a low-quality image generated by high-speed scan of the probe, and
the teacher image is a high-quality image generated by low-speed scan of the probe or frame integration of the high-speed scan.

10. A method for displaying an image of a sample in a sample observation apparatus, wherein
the sample observation apparatus includes
a microscope that irradiates a sample with a probe, detects secondary electrons from the sample, and outputs a detection signal, and
a system that generates an image based on the detection signal received from the microscope, and
the method comprises:
receiving, by the system, designation executed by a user for one or more trained models in a model database storing data of a plurality of trained models for estimating a high-quality image based on a low-quality image,
generating and displaying, by the system, a current low-quality observation image based on the detection signal, and
estimating and displaying, by the system, a high-quality image based on the current low-quality observation image according to each of the one or more trained models.
